(19) United States
(12) Patent Application Publication
(10) Pub. No.: US 2015/0361554 A1
(43) Pub. Date: Dec. 17, 2015

(54) SUBSTRATE PROCESSING APPARATUS

(71) Applicant: HITACHI KOKUSAI ELECTRIC INC., Tokyo (JP)

(72) Inventors: Tetsuo YAMAMOTO, Toyama-shi (JP); Takafumi SASAKI, Toyama-shi (JP)

(73) Assignee: HITACHI KOKUSAI ELECTRIC INC., Tokyo (JP)

(21) Appl. No.: 14/675,310

(22) Filed: Mar. 31, 2015

(30) Foreign Application Priority Data
Jun. 17, 2014 (JP) 2014124284

(51) Int. Cl. C23C 16/455

(52) U.S. Cl. CPC C23C 16/45565

(57) ABSTRACT

A mechanism includes a shower head; and a process space installed at a downstream side of the shower head. The shower head includes: a lid of the shower head having a through hole formed therein; a first dispersion mechanism having a front end to be inserted into the through hole and the other end connected to a gas supplier; a gas guide including a plate part configured to be widened in a downward direction, and a connecting part installed between the plate part and the lid, the connecting part having at least one hole formed therein; and a second dispersion mechanism installed at a downstream side of the gas guide.

### CROSS-REFERENCE TO RELATED APPLICATION

This application is based upon and claims the benefit of priority from Japanese Patent Application No. 2014-124284, filed on Jun. 17, 2014, the entire contents of which are incorporated herein by reference.

### TECHNICAL FIELD

The present disclosure relates to a substrate processing apparatus and a method of manufacturing a semiconductor device, a program.

### BACKGROUND

Recently, semiconductor devices such as a flash memory tend to be highly integrated. Accordingly, a pattern size has been significantly miniaturized. When forming such patterns, as one process of manufacture, a predetermined processing of oxidizing or nitriding on a substrate may be performed.

As a method of forming the patterns, there is a process of forming a groove between circuits and forming a seed film, a liner film or a wiring therein. This type of groove is configured to have a high aspect ratio, according to a recent miniaturization trend.

When forming the liner film and the like, it is required to form the film with a good step coverage, which has no variation in a film thickness in an upper side surface, in a middle side surface, in a lower side surface, and in a bottom part of the groove. By forming the film with a good step coverage, it is possible to make properties of semiconductor devices in each groove uniform, thereby suppressing variations in the properties of semiconductor devices.

As a hardware structure approach for making the properties of semiconductor devices uniform, for example, there is a shower head structure of a single-wafer type apparatus, having gas dispersion holes formed above a substrate so that the gas is uniformly supplied.

Further, as a substrate processing method to make the properties of semiconductor devices uniform, for example, there is an alternate gas supply method in which at least two types of process gases are alternately supplied to have them react on a surface of a substrate. In the alternate gas supply method, in order to suppress respective gases from reacting in parts other than the substrate surface, remaining gases are removed by a purge gas while respective gases are supplied.

To further improve film properties, it may be considered to use the alternate gas supply method in an apparatus that employs the shower head structure. In this case, it may be considered to provide a respective buffer space or a respective path for each gas to prevent the mixture of the gases. However, in such a case, since the structure is complicated, a lot of care is required for maintenance and cost increases as well. Accordingly, it is practical to use a showerhead where supply systems of two types of gases and a purge gas are integrated in one buffer space.

However, when using the shower head including the common buffer space for two types of gases, the remaining gases may react with each other in the shower head so that adhered matters are deposited on an inner wall of the shower head. In order to avoid such a case, it is preferable to form an exhaust hole in the buffer chamber, through which atmosphere is exhausted such that the remaining gases in the buffer chamber are efficiently removed.

When using the shower head including the common buffer space for two types of gases, the apparatus is configured so that the two types of gases and the purge gas to be supplied to a process space are not diffused in a direction to the exhaust hole for exhausting the buffer space. For this configuration, for example, a gas guide configured to form a flow of gas is installed in the buffer chamber. It is preferable that the gas guide is, for example, provided between the exhaust hole for exhausting the buffer space and a supply hole configured to supply the two types of gases and the purge gas, and is installed radially toward a dispersion plate of the shower head. In order to efficiently exhaust the gases from an inner space of the gas guide, the inside of the gas guide and the exhaust hole for exhausting the buffer space, in particular, an outer peripheral end of the gas guide and the exhaust hole may be made to be in communication with one another.

For the shower head with a complicated structure as above, it may be considered that the gases become stagnant between respective parts and thus, byproducts are adhered to those parts. It is a concern that the generated byproducts may cause degradation in device properties or a decrease in a yield rate.

### SUMMARY

Some embodiments of the present disclosure provide a mechanism capable of suppressing the generation of byproducts, even in the complicated structure as explained above.

According to an aspect of the present disclosure, there is provided a mechanism, including: a shower head; and a process space installed at a downstream side of the shower head. The shower head includes a lid of the shower head having a through hole formed therein; a first dispersion mechanism having a front end to be inserted into the through hole and the other end connected to a gas supplier; a gas guide including a plate part configured to be widened in a downward direction, and a connecting part installed between the plate part and the lid, the connecting part having at least one hole formed therein; and a second dispersion mechanism installed at a downstream side of the gas guide.

### BRIEF DESCRIPTION OF THE DRAWINGS

FIG. 1 is a view illustrating a substrate processing apparatus according to a first embodiment of the present disclosure.

FIG. 2 is an explanatory view of a first dispersion mechanism according to the first embodiment.

FIG. 3 is an explanatory view for explaining the relationship between a gas guide and the first dispersion mechanism according to the first embodiment.

FIG. 4 is a flowchart illustrating a substrate processing process of the substrate processing apparatus shown in FIG. 1.

FIG. 5 is a flowchart illustrating the details of a film forming process shown in FIG. 1.

FIG. 6 is a view illustrating a substrate processing apparatus according to a second embodiment of the present disclosure.

FIG. 7 is a view illustrating a substrate processing apparatus according to a third embodiment of the present disclosure.

FIG. 8 is an explanatory view explaining another embodiment of the first dispersion mechanism of the present disclosure.

### DETAILED DESCRIPTION

Hereinafter, the first embodiment of the present disclosure will be described.

### Apparatus Configuration

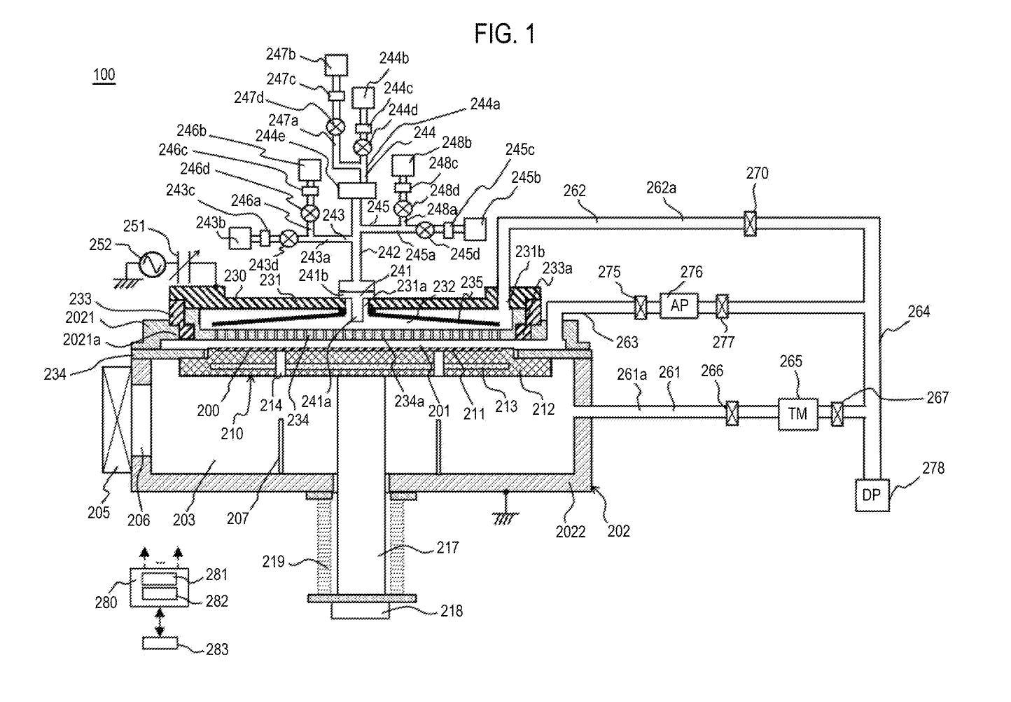

The configuration of a substrate processing apparatus 100 according to this embodiment is shown in FIG. 1. The substrate processing apparatus 100 is, as shown in FIG. 1, configured as a single-wafer type substrate processing apparatus.

### (Process Vessel)

As shown in FIG. 1, the substrate processing apparatus 100 is provided with a process vessel 202. The process vessel 202 is configured, for example, as a flat airtight vessel having a circular cross section. In addition, the process vessel 202 may be made, for example, of metal, such as aluminum (Al) or stainless steel (SUS). A process space 201, in which a wafer 200 such as a silicon wafer as a substrate is processed, and a transfer space 203, through which the wafer 200 passes when the wafer 200 is transferred to the process space 201, are formed in the process vessel 202. The process vessel 202 may be configured with an upper vessel 2021 and a lower vessel 2022. A partition plate 204 is installed between the upper vessel 2021 and the lower vessel 2022.

A substrate loading/unloading port 206 adjacent to a gate valve 205 is installed in a side surface of the lower vessel 2022. The wafer 200 may move into and out of a transfer chamber (not shown) through the substrate loading/unloading port 206. A plurality of lift pins 207 are installed in a bottom portion of the lower vessel 2022. In addition, the lower vessel 2022 is connected to a ground.

A substrate support 210 supporting the wafer 200 is installed in the process space 201. The substrate support 210 mainly includes a mounting surface 211 having the wafer 200 mounted thereon, a substrate mounting stand 212 having the mounting surface 211 on a surface thereof, and a heater 213 as a heating source contained in the substrate mounting stand 212. Through holes 214 that are to be penetrated by the lift pins 207 are formed in the substrate mounting stand 212 at positions corresponding to the lift pins 207, respectively.

The substrate mounting stand 212 is supported by a shaft 217. The shaft 217 penetrates through a bottom portion of the process vessel 202 and is also connected to an elevating instrument 218 outside the process vessel 202. By operating the elevating instrument 218 to raise up or lower down the shaft 217 and the substrate mounting stand 212, the wafer 200 mounted on the substrate mounting surface 211 can be raised up or lowered down. In addition, a periphery of a lower end of the shaft 217 is covered with a bellows 219, thereby maintaining the interior of the process vessel 202 to be airtight.

When the wafer 200 is transferred, the substrate mounting stand 212 is lowered down such that the substrate mounting surface 211 is located at a position facing the substrate loading/unloading port 206 (wafer transfer position). When the wafer 200 is processed, the substrate mounting stand 212 is raised up such that the wafer 200 is located at a processing position (wafer processing position) in the process space 201 as shown in FIG. 1.

Specifically, when the substrate mounting stand 212 is lowered down to the wafer transfer position, upper ends of the lift pins 207 protrude from an upper surface of the substrate mounting surface 211 so that the lift pins 207 support the wafer 200 from below. In addition, when the substrate mounting stand 212 is raised up to the wafer processing position, the lift pins 207 are sunken from the upper surface of the substrate mounting surface 211 so that the substrate mounting surface 211 supports the wafer 200 from below. Further, since the lift pins 207 may be in direct contact with the wafer 200, they are preferably formed, for example, of quartz, alumina or the like.

A shower head 230 as a gas dispersion mechanism may be installed at an upper portion (upstream side) of the process space 201. A through hole (a gas supply hole) 231a, through which a first dispersion mechanism (a process chamber side gas supply pipe) 241 is inserted, is formed in a lid 231 of the shower head 230. The first dispersion mechanism 241 includes a front end portion 241a that is inserted into the shower head 230 and a flange 241b that is secured to the lid 231.

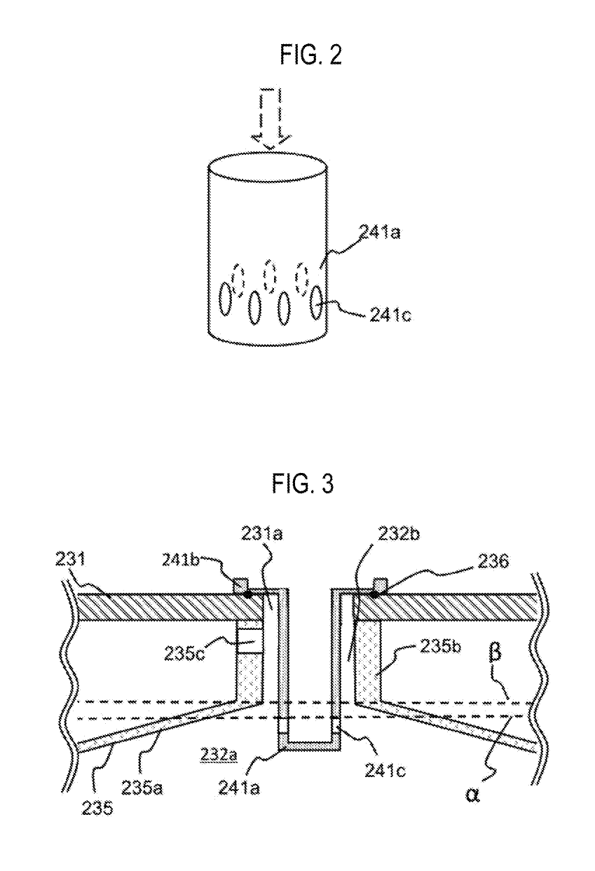

FIG. 2 is an explanatory view explaining the front end portion 241a of the first dispersion mechanism 241. A dotted line arrow represents a direction of a gas supply. The front end portion 241a is configured to have a pillar shape, for example, a cylinder shape. Dispersion holes 241c are formed on a side surface of the cylinder. A gas supplied from a gas supplier (supply system), which is described later, is supplied to a buffer space 232 through the front end portion 241a and the dispersion holes 241c.

The lid 231 of the shower head 230 may be formed of a conductive metal and used as an electrode for generating plasma in the buffer space 232 or the process space 201. An insulation block 233 may be installed between the lid 231 and the upper vessel 2021 to insulate the lid 231 and the upper vessel 2021 from each other.

The shower head 230 may include a dispersion plate 234 as a second dispersion mechanism for dispersing gases. The buffer space 232 is at the upstream side of this dispersion plate 234, and the process space 201 is at its downstream side. A plurality of through holes 234a may be formed in the dispersion plate 234. The dispersion plate 234 may be disposed to face the substrate mounting surface 211.

The upper vessel 2021 has a flange 2021a and the insulation block 233 is mounted and secured on the flange 2021a. The insulation block 233 has a flange 233a, and the dispersion plate 234 is mounted and secured on the flange 233a. In addition, the lid 231 is secured to the upper surface of the insulation block 233. With this structure, it is possible to remove, from above, the lid 231, the dispersion plate 234, and the insulation block 233 in this order.

Further, in this embodiment, since a plasma generator described below is connected to the lid 231, the insulation block 233 is installed to prevent power from transmitting to the upper vessel 2021. In addition, the dispersion plate 234 and the lid 231 are installed on the insulation member. However, the present disclosure is not limited thereto. For example, if there is no plasma generator, the dispersion plate 234 may be secured to the flange 2021 a, and the lid 231 may be secured to a portion of the upper vessel 2021 other than the flange 2021a. That is, it may be any box structure where the lid 231 and the dispersion plate 234 are removed from above in this order.

A gas guide 235 configured to guide the flow of a supplied gas is installed in the buffer space 232. The details of the gas guide 235 will be described later.

### (Supply System)

The process chamber side gas supply pipe 241 is connected to the gas supply hole 231 a that is installed in the lid 231 of the shower head 230. A common gas supply pipe 242 is connected to the process chamber side gas supply pipe 241. A flange is installed in the process chamber side gas supply pipe 241. The flange at a downstream side is secured to the lid 231 by a screw or the like. The flange at an upstream side is secured to a flange of the common gas supply pipe 242.

Since the interior of the process chamber side gas supply pipe 241 is in communication with the interior of the common gas supply pipe 242, the gas supplied from the common gas supply pipe 242 is supplied into the shower head 230 through the process chamber side gas supply pipe 241 and the gas supply hole 231 a.

A first gas supply pipe 243a, a second gas supply pipe 244a, and a third gas supply pipe 245a are connected to the common gas supply pipe 242. The second gas supply pipe 244a is connected to the common gas supply pipe 242 through a remote plasma generator 244e.

A first component-containing gas is mainly supplied from a first gas supply system 243 including the first gas supply pipe 243a. A second component-containing gas is mainly supplied from a second gas supply system 244 including the second gas supply pipe 244a. From a third gas supply system 245 including the third gas supply pipe 245a, an inert gas is mainly supplied when processing the wafer and a cleaning gas is mainly supplied when cleaning the shower head 230 or the process space 201.

### (First Gas Supply System)

In the first gas supply pipe 243a, a first gas supply source 243b, a mass flow controller (MFC) 243c as a flow rate controller (flow rate control part), and a valve 243d as an opening/closing valve are installed in this order from an upstream side.

The first component-containing gas is supplied to the shower head 230 from the first gas supply pipe 243a through the mass flow controller 243c, the valve 243d, and the common gas supply pipe 242.

The first component-containing gas may be a precursor gas, that is, one of process gases. Here, the first component may be, for example, titanium (Ti). That is, the first component-containing gas may be, for example, a titanium-containing gas. In addition, the first component-containing gas may be in any one of a solid, a liquid and a gas at a normal temperature and at a normal pressure. If the first component-containing gas is a liquid at a normal temperature and at a normal pressure, a vaporizer (not shown) may be installed between the first gas supply source 243b and the mass flow controller 243c. Here, the first component-containing gas will be described as a gas.

At a downstream side of the valve 243d, the first gas supply pipe 243a is connected to a downstream end of a first inert gas supply pipe 246a. In the first inert gas supply pipe 246a, an inert gas supply source 246b, a mass flow controller (MFC) 246c as a flow rate controller (flow rate control part), and a valve 246d as an opening/closing valve are installed in this order from an upstream side.

Here, the inert gas may be, for example, a nitrogen (N₂) gas. In addition, the inert gas may include, for example, a rare gas, such as a helium (He) gas, a neon (Ne) gas, and an argon (Ar) gas, in addition to a N₂ gas.

The first gas supply system 243 (also referred to a titanium-containing gas supply system) is mainly configured by the first gas supply pipe 243a, the mass flow controller 243c, and the valve 243d.

Further, a first inert gas supply system is mainly configured by the first inert gas supply pipe 246a, the mass flow controller 246c, and the valve 246d. In addition, the inert gas supply source 246b and the first gas supply pipe 243a may also be included in the first inert gas supply system.

Furthermore, the first gas supply source 243b and the first inert gas supply system may also be included in the first gas supply system 243.

### (Second Gas Supply System)

The remote plasma generator 244e is installed at a downstream side of the second gas supply pipe 244a. In an upstream side of the second gas supply pipe 244a, a second gas supply source 244b, a mass flow controller (MFC) 244c as a flow rate controller (flow rate control part), and a valve 244d as an opening/closing valve are installed in this order from an upstream side.

The second component-containing gas is supplied into the shower head 230 from the second gas supply pipe 244a though the mass flow controller 244c, the valve 244d, the remote plasma generator 244e, and the common gas supply pipe 242. The second component-containing gas may be made into plasma by the remote plasma generator 244e and supplied onto the wafer 200.

The second component-containing gas is one of the process gases. In addition, the second component-containing gas may be considered as a reaction gas or a modifying gas.

Here, the second component-containing gas may contain a second component other than the first component. The second component may be, for example, any one of oxygen (O), nitrogen (N), and carbon (C). In this embodiment, the second component-containing gas may be, for example, a nitrogen-containing gas. Specifically, an ammonia (NH₃) gas may be used as the nitrogen-containing gas.

The second gas supply system 244 (also referred to a nitrogen-containing gas supply system) is mainly configured by the second gas supply pipe 244a, the mass flow controller 244c, and the valve 244d.

In addition, at a downstream side of the valve 244d, the second gas supply pipe 244a is connected to a downstream end of a second inert gas supply pipe 247a. In the second inert gas supply pipe 247a, an inert gas supply source 247b, a mass flow controller (MFC) 247c as a flow rate controller (flow rate control part), and a valve 247d as an opening/closing valve are installed in this order from an upstream side.

An inert gas is supplied into the shower head 230 from the second inert gas supply pipe 247a through the mass flow controller 247c, the valve 247d, the second gas supply pipe 244a, and the remote plasma generator 244e. The inert gas may function as a carrier gas or a dilution gas in a thin film forming process S104.

A second inert gas supply system is mainly configured by the second inert gas supply pipe 247a, the mass flow controller 247c, and the valve 247d. In addition, the inert gas supply source 247b, the second gas supply pipe 244a, and the remote plasma generator 244e may also be included in the second inert gas supply system

Further, the second gas supply source 244b, the remote plasma generator 244e, and the second inert gas supply system may also be included in the second gas supply system 244.

### (Third Gas Supply System)

In the third gas supply pipe 245a, a third gas supply source 245b, a mass flow controller (MFC) 245c as a flow rate controller (flow rate control part), and a valve 245d as an opening/closing valve are installed in this order from an upstream side.

An inert gas as a purge gas is supplied to the shower head 230 from the third gas supply pipe 245a though the mass flow controller 245c, the valve 245d, and the common gas supply pipe 242.

Here, the inert gas may be, for example, a nitrogen (N₂) gas. In addition, the inert gas may include, for example, a rare gas, such as a helium (He) gas, a neon (Ne) gas, and an argon (Ar) gas, in addition to the N₂ gas.

At a downstream side of the valve 245d, the third gas supply pipe 245a is connected to a downstream end of a cleaning gas supply pipe 248a. In the cleaning gas supply pipe 248a, a cleaning gas supply source 248b, a mass flow controller (MFC) 248c as a flow rate controller (flow rate control part), and a valve 248d as an opening/closing valve are installed in this order from an upstream side.

The third gas supply system 245 is mainly configured by the third gas supply pipe 245a, the mass flow controller 245c, and the valve 245d.

Further, a cleaning gas supply system is mainly configured by the cleaning gas supply pipe 248a, the mass flow controller 248c and the valve 248d. In addition, the cleaning gas supply source 248b and the third gas supply pipe 245a may also be included in the cleaning gas supply system.

Furthermore, the third gas supply source 245b and the cleaning gas supply system may also be included in the third gas supply system 245.

In a substrate processing process, an inert gas may be supplied into the shower head 230 from the third gas supply pipe 245a through the mass flow controller 245c, the valve 245d, and the common gas supply pipe 242. Further, in a cleaning process, the cleaning gas may be supplied into the shower head 230 through the mass flow controller 248c, the valve 248d, and the common gas supply pipe 242.

In the substrate processing process, the inert gas supplied from the inert gas supply source 245b may act as a purge gas with which the process vessel 202 or the shower head 230 having the gas collected therein are purged. Further, in the cleaning process, the inert gas may act as a carrier gas or a dilution gas of the cleaning gas.

In the cleaning process, the cleaning gas supplied from the cleaning gas supply source 248b may act as the cleaning gas that removes byproducts adhered to the shower head 230 or the process vessel 202.

Here, the cleaning gas may be, for example, a nitrogen trifluoride (NF₃) gas. In addition, the cleaning gas may include, for example, a hydrogen fluoride (HF) gas, a chlorine trifluoride (ClF₃) gas, a fluorine (F₂) gas, or a combination thereof

Subsequently, with reference to FIG. 3, specific structures of the first dispersion mechanism 241, the gas guide 235, and the lid 231 will be described. FIG. 3 is an enlarged view of the periphery of the first dispersion mechanism 241 of FIG. 1 and is an explanatory view explaining the specific structures of the first dispersion mechanism 241, the gas guide 235, and the lid 231.

The first dispersion mechanism 241 includes the front end portion 241 a and the flange 241b. The front end portion 241a is inserted from above the through hole 231a. A lower surface of the flange 241b is secured to an upper surface of the lid 231 by screws or the like. An upper surface of the flange 241b is secured to the flange of the gas supply pipe 242 by screws or the like. An O-ring 236 may be installed between the flange 241b and the lid 231 to make the space in the shower head 230 airtight. It is possible to remove the first dispersion mechanism 241 separately from the lid 231. When removing it, the screws for securing to the gas supply pipe 242 or the screws for securing to the lid are detached to remove it from the lid 231.

The gas guide 235 includes a plate part 235a and a connecting part 235b.

The plate part 235a is plates that guide a gas supplied from the dispersion holes 241c of the first dispersion mechanism 241 to the dispersion plate 234. The plate part 235a has a cone body with, for example, a conical shape, having a diameter expanding toward the dispersion plate 234. The gas guide 235 has lower end portions that are positioned outside the through holes 234a at the most outer peripheral side of the dispersion plate 234.

The connecting part 235b is configured to connect the lid 231 and the plate part 235a. An upper end portion of the connecting part 235b is secured to the lower surface of the lid 231 by a screw or the like (not shown). A lower end portion thereof is connected to the plate part 235a by welding or the like. The connecting part 235b may have a pillar shape, for example, a cylinder shape. The connecting part 235b may be adjacent to a side wall of the front end portion 241a with a gap 232b therebetween. With the gap 232b therebetween, a concern that a physical contact with the connecting part 235b may occur when the first dispersion mechanism 241 is removed from the lid 231 can be avoided. By avoiding the physical contact, the removal of the first dispersion mechanism 241 is facilitated so that generation of particles caused by such physical contact is suppressed.

However, it may be considered that the supplied gas is formed into a film and adhered to the surface of the first dispersion mechanism 241 or the gas guide 235 in the shower head 230. The film formed may have a non-uniform film density or a non-uniform film thickness, unlike the film formed on a substrate in the process space. It is because, while the process space satisfies processing conditions for having a uniform film quality, the interior of the shower head 230 does not satisfy such conditions. Such conditions are, for example, gas concentration, temperature and pressure of the atmosphere, and the like. Since the film formed inside the shower head 230 may also have deviations in the film stress or film thickness, the film may be exfoliated easily.

Further, even in the shower head 230, the characteristics of the films adhered to the first dispersion mechanism 241 and the gas guide 235 are different. For the first dispersion mechanism 241, a high concentration gas that is supplied from the gas supplier directly collides with the inner wall of the first dispersion mechanism 241. Meanwhile, for the gas guide 235, a low concentration gas that has been dispersed by the first dispersion mechanism 241 collides with the gas guide 235. Here, the “low concentration” means the concentration that is lower than the gas concentration inside the first dispersion mechanism 241. Therefore, with respect to the thickness of the film formed per unit time, the thickness of the film adhered to the inner wall of the first distribution mechanism 241 is thicker than the thickness of the film adhered to the gas guide 235.

The adhered films may be removed by a cleaning processing. As the cleaning processing, it may be considered that the first dispersion mechanism 241, the lid 231, the gas guide 235, or the like are removed from the apparatus and immersed into a chemical solution to remove the films. When the cleaning target is removed by the chemical solution, dehydration by baking may be performed. Then, the respective parts are assembled into the apparatus. With such cleaning processing, the time in which the apparatus cannot operate, i.e., a so-called down time, is lengthened and thus, the operational efficiency of the apparatus goes down.

In this embodiment, the first dispersion mechanism 241 and the lid 231 are configured as separate parts and the first dispersion mechanism 241 is also configured to be easily removed. Specifically, the first dispersion mechanism 241 is configured to be inserted from above the through hole 231a. Since the first dispersion mechanism 241 is configured to be inserted from above the through hole 231a, it is possible to remove only the first dispersion mechanism 241 without removing other parts. Further, in order to prevent the generation of particles that may be caused by physical contact when the first dispersion mechanism 241 is raised and removed from the lid 231, the gap 232b is formed such that the wall of the connecting part 235b and the first dispersion mechanism 241 do not contact each other. Thus, with the gap 232b formed, it is possible to simply remove the first dispersion mechanism 241 without the concern of particles.

The cleaning processing discussed above may be performed for the first dispersion mechanism 241 removed from the apparatus. Meanwhile, to the lid 231 from which the first dispersion mechanism 241 has been removed, another first dispersion mechanism that does not have byproducts adhered thereto may be newly inserted and secured. In this way, since there is no need to disassemble the apparatus whenever the first dispersion mechanism 241 needs to be cleaned, it is possible to reduce a cleaning frequency of the entire apparatus.

Meanwhile, if the gap 232b is formed as above to enable easy removal, the gas may enter into the gap 232b when the gas is supplied. If the gas enters into the gap 232b, there is a concern that byproducts are generated in the gap 232b and those lead to particles.

Therefore, in this embodiment, a through hole 235c is provided in the connecting part 235b. The through hole 235c may be provided at a position closer to the lid 231 than to the dispersion holes 241c. By having the configuration as above, the gap 232b (space) between the first dispersion mechanism 241 and the gas guide 235 may be in communication with an exhaust pipe. In a shower head purge process, which is described below, it is possible to exhaust the gas from the gap 232b.

In addition, it is preferable that a height (α) of an upper end portion of the dispersion holes 241 c formed in the front end portion 241 a is located to be lower than a height (β) of the lower end portion of the connecting part 235b. If α is higher than β, a high concentration gas may be sprayed to the wall of the connecting part 235b with high pressure so that the adherence rate of the gas is increased accordingly. Thus, more byproducts may be generated. However, with the above structure in this embodiment, the high pressure gas is dispersed in a direction to the dispersion plate 234 without reaching the wall so that the generation of byproducts can be suppressed.

Further, while an example having the through hole 235c formed in the connecting part 235b has been described, the present disclosure is not limited thereto. It may be formed at another place that is at least higher than the upper end portion of dispersion holes 241c. In this way, the gas retained in the gap 232b can be removed.

In addition, as in this embodiment, it is more preferable that the through hole 235c is formed on the side wall of the connecting part 235b. When the through hole 235c is formed on the side wall, remaining matter in the through hole 231a of the lid 231 can be removed rapidly.

### (Plasma Generation Part)

A matching unit 251 and a high frequency power source 252 are connected to the lid 231 of the shower head 230. By adjusting impedance with the high frequency power source 252 and the matching unit 251, plasma is generated in the shower head 230 and the process space 201,

### (Exhaust System)

An exhaust system configured to exhaust the atmosphere of the process vessel 202 includes a plurality of exhaust pipes connected to the process vessel 202. Specifically, it includes an exhaust pipe 261 connected to the transfer space 203 (a first exhaust pipe), an exhaust pipe 262 connected to the buffer space 232 (a second exhaust pipe), and an exhaust pipe 263 connected to the process space 201 (a third exhaust pipe). In addition, an exhaust pipe 264 (a fourth exhaust pipe) is connected to a downstream side of each of the exhaust pipes 261, 262, and 263.

The exhaust pipe 261 may be connected to a side surface or a bottom surface of the transfer space 203. A TMP (Turbo Molecular Pump, a first vacuum pump) 265 as a vacuum pump realizing high vacuum or ultra-high vacuum is installed in the exhaust pipe 261. A valve 266 as a first exhaust valve for the transfer space is installed at an upstream side of the TMP 265 in the exhaust pipe 261. In addition, a valve 267 is installed at a downstream side of the TMP 265 in the exhaust pipe 261.

The exhaust pipe 262 may be connected to an upper surface or a side surface of the buffer space 232. A valve 270 is connected to the exhaust pipe 262. The exhaust pipe 262 and the valve 270 are integrally referred to as a shower head exhauster.

The exhaust pipe 263 may be connected to a side of the process space 201. An APC (Auto Pressure Controller) 276, which is a pressure adjuster configured to control the interior of the process space 201 to a predetermined pressure, is installed in the exhaust pipe 263. The APC 276 may include a valve body (not shown) with adjustable opening level and may adjust the conductance of the exhaust pipe 263 according to instructions from a controller, which is described below. A valve 277 is installed at a downstream side of the APC 276 in the exhaust pipe 263. In addition, a valve 275 is installed at an upstream side of the APC 276 in the exhaust pipe 263. The exhaust pipe 263, the valve 275, and the APC 276 are integrally referred to as a process chamber exhauster.

A DP (Dry Pump) 278 is installed in the exhaust pipe 264. As shown in the drawing, the exhaust pipe 262, the exhaust pipe 263, and the exhaust pipe 261 are connected to the exhaust pipe 264 in this order from an upstream side and the DP 278 is installed at the downstream side of them. The DP 278 is configured to exhaust the atmosphere of each of the buffer space 232, the process space 201, and the transfer space 203 through the exhaust pipe 262, the exhaust pipe 263, and the exhaust pipe 261, respectively. In addition, when the TMP 265 operates, the DP 278 may also function as an auxiliary pump thereof. Since it is difficult for the TMP 265, as a high vacuum (or ultra-high vacuum) pump, to perform, by itself, the exhaust to atmospheric pressure, the DP 278 may be used as the auxiliary pump to perform the exhaust to atmospheric pressure. In each valve of the exhaust system described above, for example, an air valve may be used.

### (Controller)

The substrate processing apparatus 100 includes a controller 280 configured to control the operations of respective parts of the substrate processing apparatus 100. The controller 280 includes at least a computer 281 and a memory device 282. The controller 280 is connected to the respective configurations described above, and is configured to invoke a program or a recipe from the memory device 282 and control the operations of the respective configurations according to instructions from a higher controller or a user. Moreover, the controller 280 may be configured as a dedicated computer or may be configured as a general-purpose computer. For example, the controller 280 according to this embodiment may be configured by preparing an external memory device 283 (for example, a magnetic tape, a magnetic disc such as a flexible disc or a hard disc, an optical disc such as a CD or DVD, a magneto-optical disc such as an MO, a semiconductor memory such as a USB memory (USB Flash Drive) or a memory card, in which the program is stored, and installing the program on the general-purpose computer through the external memory device 283. Also, a means for supplying the program to the computer is not limited to the external memory device 283. For example, the program may be supplied using communication means such as an Internet or a dedicated line, rather than through the external memory device 283. Also, the memory device 282 or the external memory device 283 may be configured as a non-transitory computer-readable recording medium. Hereinafter, these will be simply referred to as a “recording medium.” In addition, when the term “recording medium” is used herein, it may indicate only the memory device 282, only the external memory device 283, or both the memory device 282 and the external memory device 283.

### Substrate Processing Process

Next, a process of forming a thin film on the wafer 200 using the substrate processing apparatus 100 will be described. Further, in the following descriptions, operations of respective parts of the substrate processing apparatus 100 are controlled by the controller 280.

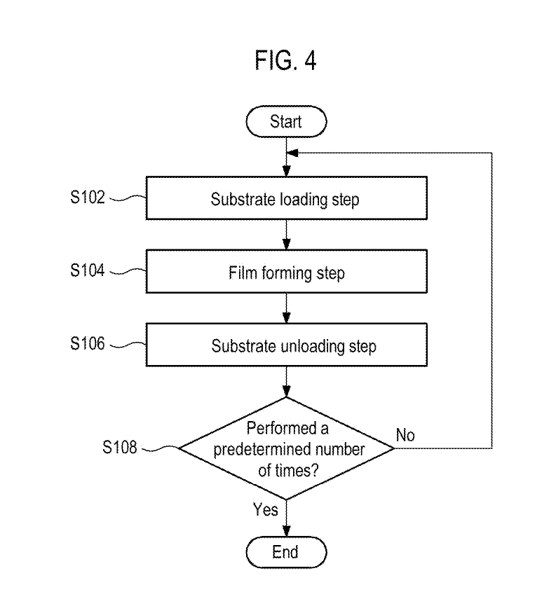

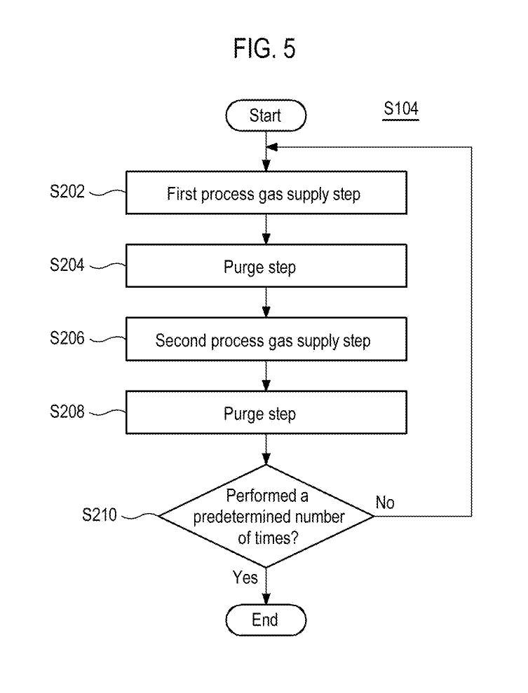

FIG. 4 is a flowchart illustrating a substrate processing process according to this embodiment. FIG. 5 is a flowchart illustrating the details of a film forming process shown in FIG. 4.

Here, an example in which a titanium nitride film is formed on the wafer 200 with a TiCl₄ gas as a first process gas and an ammonia (NH₃) gas as a second process gas will be described.

### (Substrate Loading-Mounting Process S102)

In the substrate processing apparatus 100, the substrate mounting stand 212 is lowered down to the transfer position of the wafer 200 so that the through holes 214 of the substrate mounting stand 212 are penetrated by the lift pins 207. As a result, the lift pins 207 are in a state where they protrude from the surface of the substrate mounting stand 212 by a predetermined height. Next, the gate valve 205 is opened, thereby allowing the transfer space 203 to be in communication with the transfer chamber (not shown). Then, the wafer 200 is loaded into the transfer space 203 from the transfer chamber by using a wafer transfer device (not shown). The wafer 200 is transferred onto the lift pins 207. Accordingly, the wafer 200 is supported in a horizontal position above the lift pins 207 that protrude from the surface of the substrate mounting stand 212.

When the wafer 200 is loaded into the process vessel 202, the wafer transfer device is evacuated outside of the process vessel 202 and the gate valve 205 is closed to make the interior of the process vessel 202 airtight. Then, the substrate mounting stand 212 is raised up so that the wafer 200 is mounted on the substrate mounting surface 211 provided on the substrate mounting stand 212 and subsequently raised up to the processing position in the process space 201 described above.

When the wafer 200 is loaded to the transfer space 203 and raised up to the processing position in the process space 201, the valves 266 and 267 are closed. Accordingly, a space between the transfer space 203 and the TMP 265 and a space between the TMP 265 and the exhaust pipe 264 are blocked so that the exhaust of the transfer space 203 by the TMP 265 is stopped. Meanwhile, the valves 277 and 275 are opened, thereby allowing the process space 201 to be in communication with the APC 276 and also allowing the APC 276 to be in communication with the DP 278. The APC 276 adjusts the conductance of the exhaust pipe 263, thereby controlling the exhaust flow rate of the process space 201 by the DP 278 to maintain the process space 201 to a predetermined pressure (for example, a high vacuum of 10⁻⁵ to 10⁻¹ Pa).

Moreover, in this process, while the interior of the process vessel 202 is being exhausted, a N₂ gas as an inert gas may be supplied from the inert gas supply system into the process vessel 202. In addition, while the interior of the process vessel 202 is exhausted with the TMP 265 or the DP 278, at least the valve 245d of the third gas supply system 245 may be opened so that the N₂ gas is supplied into the process vessel 202.

In addition, when the wafer 200 is mounted on the substrate mounting stand 212, a power is supplied to the heater 213 buried inside the substrate mounting stand 212 so that the surface of the wafer 200 is controlled to reach a predetermined temperature. The temperature of the wafer 200 in this embodiment may be, for example, within a range of room temperature to 500 degrees C., and preferably, a range of a room temperature to 400 degrees C. At this time, the temperature of the heater 213 may be adjusted by controlling a power on/off state for the heater 213 based on temperature information detected by a temperature sensor (not shown).

### (Film Forming Process S104)

Next, the thin film forming process S104 is performed. Hereinafter, with reference to

FIG. 5, the film forming process S104 will be described in detail. Further, the film forming process S104 is an alternate supply process of repeatedly supplying different process gases in turn.

### (First Process Gas Supply Process S202)

If the wafer 200 is heated to reach a desired temperature, the valve 243d may be opened and concurrently the mass flow controller 243c may be adjusted so that the flow rate of the TiCl₄ gas is set to a predetermined flow rate. The supply flow rate of the TiCl₄ gas may be, for example, within a range of 100 sccm to 5000 sccm. At this time, the valve 245d of the third gas supply system 245 may be opened to supply a N₂ gas from the third gas supply pipe 245a. The N₂ gas may also flow from the first inert gas supply system. In this case, the supply of the N₂ gas from the third gas supply pipe 245a may be started beforehand.

The TiCl₄ gas supplied to the process space 201 through the first dispersion mechanism 241 is supplied onto the wafer 200. The TiCl₄ gas contacts the wafer 200 to form a titanium-containing layer as “the first component-containing layer” on the surface of the wafer 200. Meanwhile, the TiCl₄ gas supplied from the first dispersion mechanism 241 is also retained in the gap 232b.

The titanium-containing layer may be formed to have a certain thickness and a certain distribution, according to, for example, a pressure inside the process vessel 202, a flow rate of the TiCl₄ gas, a temperature of the substrate mounting stand 212, and the time taken to pass the process space 201. Further, the wafer 200 may have a certain film previously formed thereon. In addition, there may be a certain pattern previously formed on the wafer 200 or the certain film thereon.

After a predetermined time has passed from the starting of the supply of the TiCl₄ gas, the valve 243d may be closed to stop the supply of the TiCl₄ gas. In the process S202 described above, as explained above with reference to FIG. 4, the valves 275 and 277 are opened so that the pressure of the process space 201 is controlled to a predetermined pressure by the APC 276. In S202, the valves of the exhaust system other than the valves 275 and 277 are all closed.

### (Purge Process S204)

Next, a N₂ gas is supplied from the third gas supply pipe 245a to purge the shower head 230 and the process space 201. Here, the valves 275 and 277 are still opened so that the pressure of the process space 201 is controlled to a predetermined pressure by the APC 276. Meanwhile, the valves of the exhaust system other than the valves 275 and 277 are all closed. Accordingly, the TiCl₄ gas that could not combine with the wafer 200 in the first process gas supply process S202 is removed from the process space 201 through the exhaust pipe 263 by the DP 278.

Next, a N₂ gas is supplied from the third gas supply pipe 245a to purge the shower head 230. While the valves 275 and 277 are closed, the valve 270 is opened. The other valves of the exhaust system remain in a closed state. That is, when purging the shower head 230, the space between the process space 201 and the APC 276 is blocked and concurrently the space between the APC 276 and the exhaust pipe 264 is blocked to stop the pressure control by the APC 276 and to allow the buffer space 232 to be in communication with the DP 278. Accordingly, the TiCl₄ gas remaining in the shower head 230 (the buffer space 232) is exhausted from the shower head 230 through the exhaust pipe 262 by the DP 278. In addition, the gas retained in the gap 232b is exhausted from the exhaust pipe 262 through the through hole 235c. At this time, the valve 277 at the downstream side of the APC 276 may be opened.

Further, in this process, the TiCl₄ gas retained in the gap 232b may be exhausted through the through hole 235c. Therefore, it is possible to significantly reduce residue in the gap 232b. As such, it is also possible to suppress generation of byproducts caused by a reaction with a gas supplied in a second gas supply process, which is described later.

When completing the purge of the shower head 230, the valves 277 and 275 are opened to resume the pressure control by the APC 276. Concurrently, the valve 270 is closed to block the space between the shower head 230 and the exhaust pipe 264. The other valves of the exhaust system remain in a closed state. At this time, the supply of the N₂ gas from the third gas supply pipe 245a may continue so that the purge of the shower head 230 and the process space 201 continues. In the purge process S204 of this embodiment, the purge through the exhaust pipe 263 is performed before and after the purge through the exhaust pipe 262. Alternatively, however, only the purge through the exhaust pipe 262 may be performed. In addition, the purge through the exhaust pipe 262 and the purge through the exhaust pipe 263 may be performed at the same time.

### (Second Process Gas Supply Process S206)

After the purge process S204, the valve 244d is opened to start the supply of an ammonia gas in a plasma state into the process space 201 through the remote plasma generator 244e and the shower head 230.

At this time, the mass flow controller 244c is adjusted such that the flow rate of the ammonia gas is set to a predetermined flow rate. In addition, the supply flow rate of the ammonia gas may be, for example, within a range of 100 sccm to 5000 sccm. Further, along with the ammonia gas, a N₂ gas as a carrier gas may flow from the second inert gas supply system. In addition, in this process, the valve 245d of the third gas supply system 245 may be also opened to supply the N₂ gas from the third gas supply pipe 245a.

The ammonia gas in a plasma state that is supplied to the process vessel 202 through the first dispersion mechanism 241 is supplied onto the wafer 200. The titanium-containing layer already formed on the wafer 200 may be modified by the plasma of the ammonia gas so that a layer containing, for example, a titanium component and a nitrogen component, is formed on the wafer 200. Meanwhile, the ammonia gas supplied from the first dispersion mechanism 241 is also retained in the gap 232b.

The modified layer may be formed to have a certain thickness, a certain distribution, and a certain penetration depth of the nitrogen component to the titanium-containing layer, depending on, for example, a pressure in the process vessel 202, a flow rate of the nitrogen-containing gas, a temperature of the substrate mounting stand 212, and a power supply state of the plasma generator.

After a predetermined time has passed, the valve 244d is closed to stop the supply of the nitrogen-containing gas.

In S206, similarly to S202 described above, the valves 275 and 277 are opened so that the pressure of the process space 201 is controlled to a predetermined pressure by the APC 276. In addition, the valves of the exhaust system other than the valves 275 and 277 are all closed.

### (Purge Process S208)

Next, a purge process that is identical to S204 is performed. As the operations of respective parts are identical to S204, the descriptions are omitted. Further, when purging the shower head purge atmosphere in the purge process S208, the ammonia gas retained in the gap 232b may be exhausted through the through hole 235c. Therefore, it is possible to significantly reduce the residue in the gap 232b. As such, it is possible to suppress generation of byproducts caused by a reaction of the first gas and the ammonia gas that are supplied when the first gas supply process is performed as described below,

### (Determination 5210)

The controller 280 determines whether the cycle discussed above is performed a predetermined number of times (n cycle).)

If it is determined that the cycle has not been performed a predetermined number of times (“NO” in S210), the cycle of the first process gas supply process S202, the purge process S204, the second process gas supply process S206, and the purge process 5208 is repeated. If the cycle is performed a predetermined number of times (“YES” in S210), the processing shown in FIG. 5 is terminated.

Returning to the descriptions of FIG. 4, subsequently, a substrate unloading process S106 is performed.

### (Substrate Unloading Process S106)

In the substrate unloading process S106, the substrate mounting stand 212 is lowered down to have the wafer 200 supported on the lift pins 207 that protrude from the surface of the substrate mounting stand 212. Accordingly, the wafer 200 is located in the transfer position from the processing position. Then, the gate valve 205 is opened and the wafer 200 is unloaded to the outside of the process vessel 202 using the wafer transfer device. At this time, the valve 245d is closed and the supply of the inert gas into the process vessel 202 from the third gas supply system 245 is stopped.

When the wafer 200 is moved to the transfer position, the valve 262 is closed to block the space between the transfer space 203 and the exhaust pipe 264. Meanwhile, the valves 266 and 267 are opened to exhaust the atmosphere of the transfer space 203 by the TMP 265 (and the DP 278). Thus, the process vessel 202 is maintained in a high vacuum (ultra-high vacuum) state (for example 10⁻⁵ Pa or less) so that a pressure difference with the transfer chamber, which is also maintained in a high vacuum (ultra-high vacuum) state (for example 10⁻⁶ Pa or less), is reduced. In this state, the gate valve 205 is opened to unload the wafer 200 from the process vessel 202 to the transfer chamber.

### (Processing Times Determination Process S108)

After the wafer 200 is unloaded, it is determined whether the thin film forming process has been performed a predetermined number of times. If it is determined that the thin film forming process has been performed the predetermined number of times, the processing is terminated. If it is determined that the thin film forming process has not been performed the predetermined number of times, the processing proceeds to the substrate loading mounting process S102 in order to start processing of the next waiting wafer 200.

### Second Embodiment

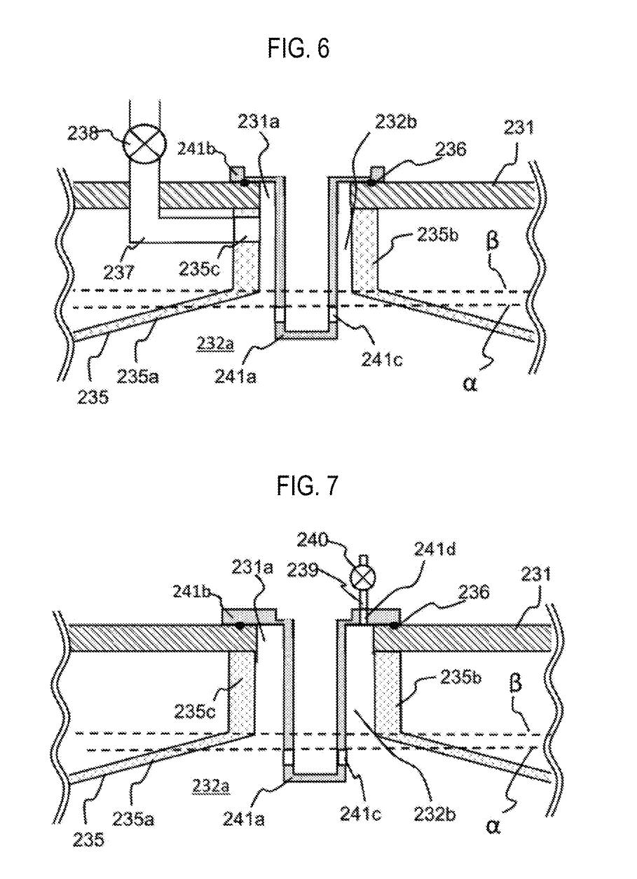

Next, the second embodiment will be described with reference to FIG. 6. The second embodiment is different from the first embodiment in that an exhaust pipe 237 installed with a valve 238 is connected to the through hole 235c. Hereinafter, the second embodiment will be described. In this regard, however, the differences from the first embodiment will be mainly described and descriptions on the configurations identical to the first embodiment are omitted.

FIG. 6 is a view explaining the relationship of the lid 231, the first dispersion mechanism 241, the gas guide 235, and the exhaust pipe 237 and the periphery of the first dispersion mechanism 241 of FIG. 1. The through hole 235c is formed in the connecting part 235b of the gas guide 235. The exhaust pipe 237 may be connected to the through hole 235c. The exhaust pipe 237 is connected to the exhaust pipe 262. The valve 238 is installed in the exhaust pipe 237. With the configuration as above, the gap 232b (space) between the first dispersion mechanism 241 and the gas guide 235 is in communication with the exhaust pipe 239.

As described below, the valve 238 is a valve to be opened in a purge process of the shower head and to be closed when the process gas is supplied. When the process gas is supplied, the valve 238 is closed so that the gas is prevented from flowing in the exhaust pipe 262. In this way, the supplied gas efficiently flows in the direction to the dispersion plate 234 and thus, it is possible to suppress unnecessary consumption of the gas.

Next, the substrate processing process in the second embodiment will be described. Since S102 to S108 of FIG. 4 are identical to those in the first embodiment, descriptions are omitted. Hereinafter, the substrate processing process of the second embodiment will be described with reference to FIG. 5.

### (First Process Gas Supply Process S202)

If the wafer 200 is heated to reach a desired temperature, the valve 243d may be opened and concurrently the mass flow controller 243c may be adjusted so that the flow rate of the TiCl₄ gas is set to a predetermined flow rate. The supply flow rate of the TiCl₄ gas may be, for example, within a range of 100 sccm to 5000 sccm. At this time, the valve 245d of the third gas supply system 245 may be opened to supply a N₂ gas from the third gas supply pipe 245a. The N₂ gas may also flow from the first inert gas supply system. In this case, the supply of the N₂ gas from the third gas supply pipe 245a may be started beforehand. Further, during the supply of the TiCl₄ gas, the valve 238 is closed. By closing the valve 238, during the supply of the TiCl₄ gas, it is possible to prevent the TiCl₄ gas from being exhausted from the through hole 235c and to uniformly supply the TiCl₄ gas in a direction toward the dispersion plate 234.

The TiCl₄ gas supplied to the process vessel 202 through the first dispersion mechanism 241 is supplied onto the wafer 200. The TiCl₄ gas contacts the wafer 200 to form a titanium-containing layer as “the first component-containing layer” on the surface of the wafer 200. Meanwhile, the TiCl₄ gas supplied from the first dispersion mechanism 241 is also retained in the gap 232b.

The titanium-containing layer may be formed to have a certain thickness and a certain distribution, according to, for example, a pressure inside the process vessel 202, a flow rate of the TiCl₄ gas, a temperature of the substrate mounting stand 212, and the time taken to pass the process space 201. Further, the wafer 200 may have a certain film previously formed thereon. In addition, there may be a certain pattern previously formed on the wafer 200 or the certain film thereon.

After a predetermined time has passed from the starting of the supply of the TiCl₄ gas, the valve 243d may be closed to stop the supply of the TiCl₄ gas. In the process S202 described above, as explained above with reference to FIG. 4, the valves 275 and 277 are opened so that the pressure of the process space 201 is controlled to a predetermined pressure by the APC 276. In S202, the valves of the exhaust system other than the valves 275 and 277 are all closed.

### (Purge Process S204)

Next, a N₂ gas is supplied from the third gas supply pipe 245a to purge the shower head 230 and the process space 201. Here, the valves 275 and 277 are still opened so that the pressure of the process space 201 is controlled to a predetermined pressure by the APC 276. Meanwhile, the valves of the exhaust system other than the valves 275 and 277 are all closed. Accordingly, the TiCl₄ gas that could not combine with the wafer 200 in the first process gas supply process S202 is removed from the process space 201 through the exhaust pipe 263 by the DP 278.

Next, a N₂ gas is supplied from the third gas supply pipe 245a to purge the shower head 230. While the valves 275 and 277 are closed, the valves 270 and 238 are opened. The other valves of the exhaust system remain in a closed state. That is, when purging the shower head 230, the space between the process space 201 and the APC 276 is blocked and concurrently the space between the APC 276 and the exhaust pipe 264 is blocked to stop the pressure control by the APC 276 and to allow the buffer space 232 and the DP 278, specifically the gap 232b and the DP 278 to be in communication. Accordingly, the TiCl₄ gas remaining in the shower head 230 (the buffer space 232) including the gap 232b is exhausted from the shower head 230 through the exhaust pipe 262 by the DP 278. At this time, the valve 277 at the downstream side of the APC 276 may be opened.

Further, in this process, the TiCl₄ gas retained in the gap 232b may be exhausted through the through hole 235c and the pipe 237. Therefore, it is possible to significantly reduce residue in the gap 232b. As such, it is also possible to suppress generation of byproducts caused by a reaction with a gas supplied in a second gas supply process, which is described later.

When completing the purge of the shower head 230, the valves 277 and 275 are opened to resume the pressure control by the APC 276. Concurrently, the valves 270 and 238 are closed to block the space between the shower head 230 and the exhaust pipe 264. The other valves of the exhaust system remain in a closed state. At this time, the supply of the N₂ gas from the third gas supply pipe 245a may continue so that the purge of the shower head 230 and the process space 201 continues. In the purge process S204 of this embodiment, the purge through the exhaust pipe 263 is performed before and after the purge through the exhaust pipe 262. Alternatively, however, only the purge through the exhaust pipe 262 may be performed. In addition, the purge through the exhaust pipe 262 and the purge through the exhaust pipe 263 may be performed at the same time.

### (Second Process Gas Supply Process S206)

After the purge process S204, the valve 244d is opened to start the supply of an ammonia gas in a plasma state into the process space 201 through the remote plasma generator 244e and the shower head 230.

At this time, the mass flow controller 244c is adjusted such that the flow rate of the ammonia gas is set to a predetermined flow rate. In addition, the supply flow rate of the ammonia gas may be, for example, within a range of 100 sccm to 5000 sccm. Further, along with the ammonia gas, a N₂ gas as a carrier gas may flow from the second inert gas supply system. In addition, in this process, the valve 245d of the third gas supply system 245 may be also opened to supply the N₂ gas from the third gas supply pipe 245a.

The ammonia gas in a plasma state that is supplied to the process vessel 202 through the first dispersion mechanism 241 is supplied onto the wafer 200. The titanium-containing layer already formed on the wafer 200 may be modified by the plasma of the ammonia gas so that a layer containing, for example, a titanium component and a nitrogen component, is formed on the wafer 200. Meanwhile, the ammonia gas supplied from the first dispersion mechanism 241 is also retained in the gap 232b.

The modified layer may be formed to have a certain thickness, a certain distribution, and a certain penetration depth of the nitrogen component to the titanium-containing layer, depending on, for example, a pressure in the process vessel 202, a flow rate of the nitrogen- containing gas, a temperature of the substrate mounting stand 212, and a power supply state of the plasma generator.

After a predetermined time has passed, the valve 244d is closed to stop the supply of the nitrogen-containing gas.

In S206, similarly to S202 described above, the valves 275 and 277 are opened so that the pressure of the process space 201 is controlled to a predetermined pressure by the APC 276. In addition, the valves of the exhaust system other than the valves 275 and 277 are all closed.

### (Purge Process S208)

Next, a purge process that is identical to S204 is performed. As the operations of respective parts are identical to S204, the descriptions are omitted. Further, in the shower head purge process, the ammonia gas retained in the gap 232b may be exhausted through the through hole 235c and the pipe 237. Therefore, it is possible to significantly reduce the residue in the gap 232b. As such, it is possible to suppress generation of byproducts caused by a reaction of the first gas and the ammonia gas that are supplied when the first gas supply process is performed as described below.

### (Determination S210)

The controller 280 determines whether the cycle discussed above is performed a predetermined number of times (n cycle).)

If it is determined that the cycle has not been performed a predetermined number of times (“NO” in S210), the cycle of the first process gas supply process S202, the purge process S204, the second process gas supply process S206, and the purge process S208 is repeated. If the cycle has been performed a predetermined number of times (“YES” in S210), the processing shown in FIG. 5 is terminated.

### Third Embodiment

Next, the third embodiment of the present disclosure will be described with reference to FIG. 7. In the third embodiment, instead of the through hole 235c of the first embodiment, a through hole 241d is formed in the flange 241b. Hereinafter, the third embodiment will be described. In this regard, however, the differences from the first embodiment will be mainly described and descriptions on the configurations identical to the first embodiment are omitted.

FIG. 7 is a view explaining the relationship of the lid 231, the first dispersion mechanism 241, the gas guide 235, and the exhaust pipe 239 and the periphery of the first dispersion mechanism 241 of FIG. 1. The through hole 241d is formed in the flange 241b. That is, the through hole 241d is formed at a position closer to the lid 231 than the dispersion holes 241c. The exhaust pipe 239 is connected to the through hole 241d. The exhaust pipe 239 is connected to the exhaust pipe 262. A valve 240 is installed in the exhaust pipe 237. By configuring as above, the gap 232b (space) between the first dispersion mechanism 241 and the gas guide 235 is in communication with the exhaust pipe 239.

As described below, the valve 240 is a valve to be opened in a purge process of the shower head and to be closed when the process gas is supplied. When the process gas is supplied, the valve is closed so that the gas is prevented from flowing in the exhaust pipe 262. In this way, the supplied gas efficiently flows in the direction of the dispersion plate 234 and thus, it is possible to suppress unnecessary consumption of the gas.

Next, the substrate processing process in the third embodiment will be described. Since S102 to S108 of FIG. 4 are identical to those in the first embodiment, descriptions are omitted. Hereinafter, the substrate processing process of the third embodiment will be described with reference to FIG. 5.

### (First Process Gas Supply Process S202)

If the wafer 200 is heated to reach a desired temperature, the valve 243d may be opened and concurrently the mass flow controller 243c may be adjusted so that the flow rate of the TiCl₄ gas is set to a predetermined flow rate. The supply flow rate of the TiCl₄ gas may be, for example, within a range of 100 sccm to 5000 sccm. At this time, the valve 245d of the third gas supply system 245 may be opened to supply a N₂ gas from the third gas supply pipe 245a. The N₂ gas may also flow from the first inert gas supply system. In this case, the supply of the N₂ gas from the third gas supply pipe 245a may be started beforehand. Further, during the supply of the TiCl₄ gas, the valve 240 is closed. By closing the valve 240, during the supply of the TiCl₄ gas, it is possible to prevent the TiCl₄ gas from being exhausted from the through hole 241d and to uniformly supply the TiCl₄ gas in a direction toward the dispersion plate 234.

The TiCl₄ gas supplied to the process vessel 202 through the first dispersion mechanism 241 is supplied onto the wafer 200. The TiCl₄ gas contacts the wafer 200 to form a titanium-containing layer as “the first component-containing layer” on the surface of the wafer 200. Meanwhile, the TiCl₄ gas supplied from the first dispersion mechanism 241 is also retained in the gap 232b.

The titanium-containing layer may be formed to have a certain thickness and a certain distribution, according to, for example, a pressure inside the process vessel 202, a flow rate of the TiCl₄ gas, a temperature of the substrate mounting stand 212, and the time taken to pass the process space 201. Further, the wafer 200 may have a certain film previously formed thereon. In addition, there may be a certain pattern previously formed on the wafer 200 or the certain film thereon.

After a predetermined time has passed from the starting of the supply of the TiCl₄ gas, the valve 243d may be closed to stop the supply of the TiCl₄ gas. In the process S202 described above, as explained above with reference to FIG. 4, the valves 275 and 277 are opened so that the pressure of the process space 201 is controlled to a predetermined pressure by the APC 276. In S202, the valves of the exhaust system other than the valves 275 and 277 are all closed.

### (Purge Process S204)

Next, a N₂ gas is supplied from the third gas supply pipe 245a to purge the shower head 230 and the process space 201. Here, the valves 275 and 277 are still opened so that the pressure of the process space 201 is controlled to a predetermined pressure by the APC 276. Meanwhile, the valves of the exhaust system other than the valves 275 and 277 are all closed. Accordingly, the TiCl₄ gas that could not combine with the wafer 200 in the first process gas supply process S202 is removed from the process space 201 through the exhaust pipe 263 by the DP 278.

Next, a N₂ gas is supplied from the third gas supply pipe 245a to purge the shower head 230. While the valves 275 and 277 are closed, the valve 270 and 240 are opened. The other valves of the exhaust system remain in a closed state. That is, when purging the shower head 230, the space between the process space 201 and the APC 276 is blocked and concurrently the space between the APC 276 and the exhaust pipe 264 is blocked to stop the pressure control by the APC 276 and to allow the buffer space 232 and the DP 278, specifically the gap 232b and the DP 278 to be in communication. Accordingly, the TiCl₄ gas remaining in the shower head 230 (the buffer space 232) including the gap 232b is exhausted from the shower head 230 through the exhaust pipe 262 by the DP 278. At this time, the valve 277 at the downstream side of the APC 276 may be opened.

Further, in this process, the TiCl₄ gas retained in the gap 232b may be exhausted through the through hole 241d and the pipe 239. Therefore, it is possible to significantly reduce residue in the gap 232b. As such, it is also possible to suppress generation of byproducts caused by a reaction with a gas supplied in a second gas supply process, which is described later.

When completing the purge of the shower head 230, the valves 277 and 275 are opened to resume the pressure control by the APC 276. Concurrently, the valves 270 and 238 are closed to block the space between the shower head 230 and the exhaust pipe 264. The other valves of the exhaust system remain in a closed state. At this time, the supply of the N₂ gas from the third gas supply pipe 245a may continue so that the purge of the shower head 230 and the process space 201 continues. In the purge process S204 of this embodiment, the purge through the exhaust pipe 263 is performed before and after the purge through the exhaust pipe 262. Alternatively, however, only the purge through the exhaust pipe 262 may be performed. In addition, the purge through the exhaust pipe 262 and the purge through the exhaust pipe 263 may be performed at the same time.

### (Second Process Gas Supply Process S206)

After the purge process S204, the valve 244d is opened to start the supply of an ammonia gas in a plasma state into the process space 201 through the remote plasma generator 244e and the shower head 230.

At this time, the mass flow controller 244c is adjusted such that the flow rate of the ammonia gas is set to a predetermined flow rate. In addition, the supply flow rate of the ammonia gas may be, for example, within a range of 100 sccm to 5000 sccm. Further, along with the ammonia gas, a N₂ gas as a carrier gas may flow from the second inert gas supply system. In addition, in this process, the valve 245d of the third gas supply system 245 may be also opened to supply the N₂ gas from the third gas supply pipe 245a.

The ammonia gas in a plasma state that is supplied to the process vessel 202 through the first dispersion mechanism 241 is supplied onto the wafer 200. The titanium-containing layer already formed on the wafer 200 may be modified by the plasma of the ammonia gas so that a layer containing, for example, a titanium component and a nitrogen component, is formed on the wafer 200. Meanwhile, the ammonia gas supplied from the first dispersion mechanism 241 is also retained in the gap 232b.

The modified layer may be formed to have a certain thickness, a certain distribution, and a certain penetration depth of the nitrogen component to the titanium-containing layer, depending on, for example, a pressure in the process vessel 202, a flow rate of the nitrogen-containing gas, a temperature of the substrate mounting stand 212, and a power supply state of the plasma generator.

After a predetermined time has passed, the valve 244d is closed to stop the supply of the nitrogen-containing gas.

In S206, similar to S202 described above, the valves 275 and 277 are opened so that the pressure of the process space 201 is controlled to a predetermined pressure by the APC 276. In addition, the valves of the exhaust system other than the valves 275 and 277 are all closed.

### (Purge Process S208)

Next, a purge process that is identical to S204 is performed. As the operations of respective parts are identical to S204, the descriptions are omitted. Further, in the shower head purge process, the ammonia gas retained in the gap 232b may be exhausted through the through hole 241d and the pipe 239. Therefore, it is possible to significantly reduce the residue in the gap 232b. As such, it is possible to suppress generation of byproducts caused by a reaction of the first gas and the ammonia gas that are supplied when the first gas supply process is performed as described below.

### (Determination S210)

The controller 280 determines whether the cycle discussed above is performed a predetermined number of times (n cycle).)

If it is determined that the cycle has not been performed a predetermined number of times (“NO” in S210), the cycle of the first process gas supply process S202, the purge process S204, the second process gas supply process S206, and the purge process S208 is repeated. If the cycle has been performed a predetermined number of times (“YES” in S210), the processing shown in FIG. 5 is terminated.

While film forming technologies have been described above as various exemplary embodiments of the present disclosure, the present disclosure is not limited to those embodiments. For example, the present disclosure can be applied to a film forming processing of other than a thin film that is exemplified above, or to other substrate processing such as a diffusion processing, an oxidation processing, a nitriding processing, a lithography processing or the like. In addition, the present disclosure can be applied to other substrate processing apparatus, such as, a thin film formation apparatus, an etching apparatus, an oxidation processing apparatus, a nitriding processing apparatus, a coating apparatus, a heating apparatus, and the like, in addition to an annealing treatment device. Further, it is possible to substitute a part of the configuration of an embodiment with the configuration of another embodiment, and also, it is possible to add the configuration of another embodiment to the configuration of a certain embodiment. In addition, for a part of the configuration of each embodiment, it is also possible to add, delete, or substitute other configurations.

Further, in the embodiments above, while TiC₁₄ has been described as an example of the first component-containing gas and Ti has been described as an example of the first component, the present disclosure is not limited thereto. For example, the first component may be various components such as Si, Zr, Hf, or the like. In addition, while NH₃ has been described as an example of the second component-containing gas and N has been described as an example of the second component, the present disclosure is not limited thereto. For example, the second element may be O or the like.

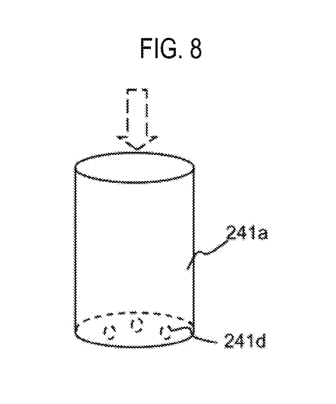

Furthermore, while it has been described that the first dispersion mechanism is pillar-shaped and the through holes are formed on its side surface, the present disclosure is not limited thereto. For example, as shown in FIG. 8, it may have a shape where a plurality of dispersion holes 241d is formed below its front end.

### Aspects of Present Disclosure

Hereinafter, aspects of the present disclosure will be additionally stated.

### Supplementary Note 1

A substrate processing apparatus, including:
a shower head; and
a process space installed at a downstream side of the shower head,
wherein the shower head includes:
a lid of the shower head having a through hole formed therein;
a first dispersion mechanism having a front end to be inserted into the through hole and the other end connected to a gas supplier;
a gas guide including a plate part configured to be widened in a downward direction, and
a connecting part installed between the plate part and the lid, the connecting part having at least one hole formed therein; and
a second dispersion mechanism installed at a downstream side of the gas guide.

### Supplementary Note 2

The substrate processing apparatus of Supplementary Note 1,
wherein the first dispersion mechanism and the connecting part of the gas guide are configured to be adjacent to each other with a gap therebetween.

### Supplementary Note 3

The substrate processing apparatus of Supplementary Note 1 or 2,
wherein the first dispersion mechanism includes a dispersion hole formed therein, and
wherein an upper end portion of the dispersion hole is positioned lower than a lower end portion of the connecting part.

### Supplementary Note 4

The substrate processing apparatus of any one of Supplementary Notes 1 to 3,
wherein a dispersion hole formed in the first dispersion mechanism is positioned lower than the hole of the connecting part.

### Supplementary Note 5

The substrate processing apparatus of any one of Supplementary Notes 1 to 4,
wherein the shower head includes an exhaust hole formed therein, the exhaust hole being connected to an exhauster.

### Supplementary Note 6

The substrate processing apparatus of any one of Supplementary Notes 1 to 5,
wherein the first dispersion mechanism is inserted from above the lid part.

### Supplementary Note 7

The substrate processing apparatus of any one of Supplementary Notes 1 to 6,
wherein a hole formed in the first dispersion mechanism is connected to an exhaust pipe on which an opening/closing valve is installed.

### Supplementary Note 8

A method of manufacturing a semiconductor device, including
supplying a gas from a gas supplier to a process space through a shower head; and
processing a substrate in the process space;
wherein a through hole is formed in a lid of the shower head,
wherein the shower head includes:
a first dispersion mechanism having a front end to be inserted into the through hole and the other end connected to the gas supplier;
a gas guide including a plate part configured to be widened in a downward direction, and a pillar-shaped connecting part installed between the plate part and the lid, the connecting part having at least one hole formed therein; and
a second dispersion mechanism installed at a downstream side of the gas guide, and
wherein the gas is supplied to the process space through the first dispersion mechanism and the second dispersion mechanism.

### Supplementary Note 9

A program that causes execution of a method of manufacturing a semiconductor device, the method including:
supplying a gas from a gas supplier to a process space through a shower head; and
processing a substrate in the process space;
wherein a through hole is formed in a lid of the shower head,
wherein the shower head includes:
a first dispersion mechanism having a front end to be inserted into the through hole and the other end connected to the gas supplier;
a gas guide including a plate part configured to be widened in a downward direction, and a cylinder-shaped connecting part installed between the plate part and the lid, the connecting part having a hole formed therein; and
a second dispersion mechanism installed at a downstream side of the gas guide, and
wherein the gas is supplied to the process space through the first dispersion mechanism and the second dispersion mechanism.

### Supplementary Note 10

A non-transitory computer-readable recording medium storing a program that causes execution of a method of manufacturing a semiconductor device, the method including:
supplying a gas from a gas supplier to a process space through a shower head; and
processing a substrate in the process space;
wherein a through hole is formed in a lid of the shower head,
wherein the shower head includes:
a first dispersion mechanism having a front end to be inserted into the through hole and the other end connected to the gas supplier;
a gas guide including a plate part configured to be widened in a downward direction, and a pillar-shaped connecting part installed between the plate part and the lid, the connecting part having at least one hole formed therein; and
a second dispersion mechanism installed at a downstream side of the gas guide, and
wherein the gas is supplied to the process space through the first dispersion mechanism and the second dispersion mechanism.

### Supplementary Note 11

A substrate processing apparatus, including:
a shower head including:
   a lid of the shower head having a through hole formed therein;
   a first dispersion mechanism having a front end to be inserted into the through hole and the other end connected to a gas supplier;
   a gas guide including a plate part configured to be widened in a downward direction, and a connecting part installed between the plate part and the lid; and
   a second dispersion mechanism installed at a downstream side of the gas guide;
a through hole configured to allow a space between the first dispersion mechanism and the gas guide to be in communication with a shower head exhauster installed in the shower head; and
a process space installed at a downstream side of the shower head.

According to the present disclosure, even in the complicated structure as described above, it is possible to suppress the generation of byproducts.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to lid such forms or modifications as would fall within the scope and spirit of the disclosures.

What is claimed is:

1. A substrate processing apparatus, comprising:
a shower head; and
a process space installed at a downstream side of the shower head, wherein the shower head includes:
a lid of the shower head having a through hole formed therein;
a first dispersion mechanism having a front end protruding from the through hole and the other end connected to a gas supplier;
a gas guide including a guide part configured to be widened in a downward direction, and a connecting part installed between the guide part and the lid, the connecting part having at least one hole formed therein; and
a second dispersion mechanism installed at a downstream side of the gas guide.
